(19) United States
(12) Patent Application Publication
(10) Pub. No.: US 2025/0299513 A1
(43) Pub. Date: Sep. 25, 2025

(54) AN OPTICAL UNDER-DISPLAY FINGERPRINT SENSOR

(71) Applicant: FINGERPRINT CARDS ANACATUM IP AB, GÖTEBORG (SE)

(72) Inventors: Jun LIU, SHANGHAI (CN); Hans MARTINSSON, HÄLLINGSJÖ (SE)

(73) Assignee: FINGERPRINT CARDS ANACATUM IP AB, GÖTEBORG (SE)

(21) Appl. No.: 18/862,340

(22) PCT Filed: May 9, 2023
(86) PCT No.: PCT/SE2023/050453

§ 371 Date: Nov. 1, 2024

(30) Foreign Application Priority Data
May 11, 2022 (CN) 202221129695.X

(51) Int. Cl. G06V 40/13; G01D 5/24; G06V 40/12; G06V 40/40

(52) U.S. Cl. CPC G06V 40/1318; G01D 5/24; G06V 40/1382; G06V 40/45

(57) ABSTRACT

The present invention relates to an optical fingerprint sensor configured to be arranged under a cover structure comprising a display, the optical fingerprint sensor comprising: an array of photodetectors for detecting light transmitted from an object located on an opposite side of the cover structure; an array of light emitters for illuminating the object, the array of light emitters is interleaved with the array of photodetectors, and a collimator structure arranged to cover the array of light emitters and the array of photodetectors, the collimator structure comprising a first set of collimators aligned with the photodetectors and each being configured to provide a predetermined field of view, and a second set of collimators aligned with the light emitters, and each being configured to provide a predetermined field of illumination.

### FIELD OF THE INVENTION

The present invention relates to an optical fingerprint sensor configured to be arranged under a cover structure comprising a display. The invention further relates to an electronic device comprising an optical fingerprint sensor.

### BACKGROUND OF THE INVENTION

Biometric systems are widely used as means for increasing the convenience and security of personal electronic devices, such as mobile phones etc. Fingerprint sensing systems, in particular, are now included in a large proportion of all newly released consumer electronic devices, such as mobile phones.

Optical fingerprint sensors have been known for some time and may be a feasible alternative to e.g., capacitive fingerprint sensors in certain applications, for example in under-display applications. Optical fingerprint sensors may for example be based on the pinhole imaging principle and/or may employ micro-channels, i.e., collimators or microlenses to focus incoming light onto an image sensor.

In some applications it is desirable to mount the optical fingerprint sensor under a display or cover. For this type of applications an external illumination instead of display emission may be used to cooperate with the optical fingerprint detection module. However, to achieve uniform illumination on the finger surface by the external light source the point light emission has to be diffused by a dedicated and complicated light guide.

Another possibility is to add a pin hole layer in a pixel definition layer so that the reflected light from finger can pass through the display. However, this needs design- and manufacture modification of the display stack up and would hamper the display performance compared with the non-pin hole display area.

Further, an optical imaging component such as pinholes or micro-lens may be manufactured on the sensor pixel. However, this inversely reduces the display performance. When no optical component is used on the sensor pixel, a limited distance between a sensor layer and finger surface is required to ensure a clear fingerprint image, however, this will deteriorate the fingerprint detection performance, especially when a protection film is used on the screen.

Additionally, ultrasonic detections require a module laminated upon the display backside without airgap, which may hamper the display performance.

Accordingly, there is room for improvement with regards to fingerprint imaging using fingerprint sensor under displays or covers.

### SUMMARY

In view of above-mentioned and other drawbacks of the prior art, it is an object of the present invention to provide an optical fingerprint sensor that at least alleviates some of the drawbacks of prior art.

According to a first aspect of the invention, there is provided an optical fingerprint sensor configured to be arranged under a cover structure comprising a display.

The optical fingerprint sensor comprises an array of photodetectors for detecting light transmitted from an object located on an opposite side of the cover structure; an array of light emitters for illuminating the object, where the array of light emitters is interleaved with the array of photodetectors, and a collimator structure arranged to cover the array of light emitters and the array of photodetectors. The collimator structure comprising a first set of collimators aligned with the photodetectors and each being configured to provide a predetermined field of view, and a second set of collimators aligned with the light emitters, and each being configured to provide a predetermined field of illumination.

The present invention is based on the realization of a pixel-wised crossed emitter and receiver with specified filed of illumination and field of view controlled by the optical stack comprising the collimator structure. By means of the embodiments provided by the present invention, there is no need for lamination of detection layers on the display or modifications of the display panel that will impact the display performance.

The array of light emitters and the array of photodetectors may be considered a mixed array of light emitters and photodetectors.

The photodetectors may be based on thin-film transistor (TFT) technology. Such sensors provide a cost-efficient solution for under display fingerprint imaging sensors. The TFT image sensor may be a back illuminated TFT image sensor or a front illuminated TFT image sensor. The TFT image sensor may be arranged as a Hot-zone, Large Area or Full display solution. Other suitable types of photodetector technology include CMOS or CCD sensors.

According to embodiments, a radius of the predetermined field of illumination at an object plane may be larger than a half pitch of the light emitters. Advantageously, the illuminated area covers the sampling area at the object plane. This requires that the radius of the circular area illuminated by each light emitter is larger than half the pitch and will further depend on if the light emitters are arranged in a quadratic grid or in a hexagonal grid. For a quadratic grid the minimal radius of the predetermined field of illumination is pitch/sqrt(2) and for a hexagonal grid the minimal radius of the predetermined field of illumination is pitch/sqrt(3).

According to embodiments, a radius of the predetermined field of view may be less than a half pitch of the photodetectors. A sampling area pitch depends on the requirement of image density, i.e., dot per inch, DPI, and the sampling radius, i.e., the radius of the predetermined field of view should be equal or less than the half pitch of the photodetectors.

According to embodiments, the collimator structure may further comprise an array of microlenses, wherein each collimator of the first set and the second set comprises an aperture or opening covered with a respective microlens. The apertures and microlenses provide for tailoring the field of view and the field of illumination.

According to embodiments, the collimator structure may comprise a first opaque layer, wherein the microlenses are arranged in separate openings of the first opaque layer. The first opaque layer is a black layer which prevents light from reaching the photodetectors that have not passed through a microlens, thus, so called leakage light is reduced. The openings are part of the apertures of the collimator structure.

Each microlens may be arranged to redirect light onto a single pixel.

According to embodiments, the collimator structure may comprise a second opaque layer having through-holes aligned with respective light emitters and photodetectors. The second opaque layer is arranged between the first opaque layer and the arrays of light emitters and photodetectors. The second opaque layer may be an intermediate or interleaved black layer between the first opaque layer and the mixed array of light emitters and photodetectors.

According to embodiments, the collimator structure may comprise individual optical filter elements arranged in each of the through-holes. The optical filters may be visible color filters, such as red, green and blue color filter, or bandpass filter centered around e.g., 810 nm, 850 nm or 940 nm.

The optical filter elements may be color filter elements having a spectral transmission band corresponding to a color of light thereby being configured to allow the transmission of light in a specific spectral band.

According to embodiments, the individual optical filter elements may comprise at least two different filter element types arranged in different through-holes and having different wavelength transmission bands and/or polarization. The spectral transmission bands of the two filter element types may be non-overlapping. The optical filter element types may further comprise or be an infrared cut filter.

According to embodiments, the optical filter elements arranged in each of the through-holes aligned with the light emitters may be different from the optical filter elements arranged in each of the through-holes aligned with the photodetectors. In other words, the light illuminating the object may be filtered or polarized according to a different spectral band compared to the filtering or polarization of the light provided by the filters at the photodetectors. Using different filters provide for tailoring different imaging channels each associated with a group of emitters and photodetectors. An imaging channel preferably relates to a color channel that can be used for spoof detection. For example, Red/Green/Blue color channel information can differentiate a real finger reflected signal and spoofed finger material reflected signal.

According to embodiments, the optical fingerprint sensor may comprise a third opaque layer between the second opaque layer and the array of photodetectors and the array of light emitters, the third opaque layer having separate openings for each light emitter and photodetector, where the openings for the photodetectors are smaller than a diameter of the respective aligned through-holes of the second opaque layer. The third opaque layer provides for further tailoring of the field of view and field of illumination. The third opaque layer may be a metal layer interleaved or arranged between the second opaque layer and the mixed array of photodetectors and light emitters.

According to embodiments, the collimator structure may comprise a third opaque layer and an optical filter layer interleaved between the second opaque layer and the third opaque layer, the third opaque layer being arranged closer to the array of photodetectors and the array of light emitters than the second opaque layer. In this case, the filter layer may be arranged to cover the array of photodetectors and the array of light emitters, a single layer, and the third layer may be a so-called black layer. The third opaque layer may have separate openings for each light emitter and photodetector, where the openings for the photodetectors may be smaller than a diameter of the respective aligned through-holes in the second opaque layer.

According to embodiments, the optical fingerprint sensor may comprise an optically transparent substrate arranged stacked between the array of microlenses and the second opaque layer to cover the second opaque layer. The optically transparent layer provides for tailoring the distance between the array of light emitters and photodetectors to thereby tailor the field of view and field of illumination.

According to embodiments, the array of light emitters may be interleaved with the array of photodetectors in a square crossed arrangement.

According to embodiments, the array of light emitters may be interleaved with the array of photodetectors in an oblique crossed arrangement.

According to embodiments, the array of light emitters and the array of photodetectors may be distributed on a single substrate die.

According to embodiments, the optical fingerprint sensor may comprise a set of capacitive sensing elements interleaved with the array of light emitters and the array of photodetectors, the capacitive sensing elements are configured to detect a capacitive coupling between an object touching a sensing surface of the optical fingerprint sensor, and provide a sensing signal indicative of the capacitive coupling. The capacitive sensing elements in conjunction with the optical sensing of the photodetectors provide for improved liveness or spoof detection. For example, the capacitive sensor may detect a fingerprint, while the optical sensor performs spoof detection. In one such implementation, an infrared emitter and photodetector for detecting infra-red light may be used for performing spoof detection alongside the fingerprint authentication performed by the capacitive sensor. This provides for an improved security fingerprint sensor. A spoof material such as rubber and plastic reflect IR light in a different way compared to a live object such as a finger. This is used for performing liveness detection using IR light as is known per se in the art.

According to embodiments, the capacitive sensing elements being arranged on the silicon die as the array of light emitters and the array of photodetectors.

The outer surface of a display panel or cover under which the optical fingerprint sensor is arranged may also be referred to as a sensing surface. The operating principle of the described optical fingerprint sensor is that light emitted by controllable light emitters, will be reflected by a finger placed on the sensing surface, and the reflected light is received by the microlenses and subsequently redirected onto a corresponding photodetector in the photodetector array. By combining the signals from each of the photodetectors an image representing the fingerprint can be formed and subsequent biometric verification can be performed.

According to a second aspect of the invention, there is provided an electronic device comprising: a cover structure comprising a display;
the optical fingerprint sensor according to any one of the herein disclosed or derived embodiments, and processing circuitry configured to: receive a signal from the optical fingerprint sensor indicative of a fingerprint of a finger touching the at least partly transparent display panel, perform a fingerprint authentication procedure based on information comprised in the signal.

The display may for example be based on OLED, LCD, μLED and similar technologies.

The electronic device may be e.g., a mobile device such as a mobile phone (e.g. Smart Phone), a tablet, a phablet, etc.

Further effects and features of the second aspect of the invention are largely analogous to those described above in connection with the first aspect of the invention.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail, with reference to the appended drawings showing an example embodiment of the invention, wherein:

FIG. 1 schematically illustrates an example of an electronic device according to embodiments of the invention;

FIG. 2 is a schematic box diagram of an electronic device according to embodiments of the invention;

FIG. 3A is a conceptual top view of interleaved arrays of light emitters and photodetectors according to an embodiment of the invention;

FIG. 3B is a conceptual top view of interleaved arrays of light emitters and photodetectors according to an embodiment of the invention;

FIG. 4A is a conceptual cross-sectional view of an optical fingerprint sensor according to an embodiment of the invention;

FIG. 4B is a conceptual cross-sectional view of an optical fingerprint sensor under a cover structure according to an embodiment of the invention;

FIG. 5A is a conceptual cross-sectional view of an optical fingerprint sensor according to an embodiment of the invention;

FIG. 5B is a conceptual cross-sectional view of an optical fingerprint sensor under a cover structure according to an embodiment of the invention;

FIG. 6 is a conceptual cross-sectional view of an optical fingerprint sensor under a cover structure according to an embodiment of the invention; and

FIG. 7 is a conceptual top view of interleaved arrays of light emitters, photodetectors, and capacitive sensing elements according to an embodiment of the invention.

### DETAILED DESCRIPTION OF EXAMPLE EMBODIMENTS

In the present detailed description, various embodiments of the optical fingerprint sensor according to the present invention are mainly described with reference to an optical fingerprint sensor arranged under a display panel. However, it should be noted that the described imaging device also may be used in other optical fingerprint imaging applications such as in an optical fingerprint sensor located under other types of covers.

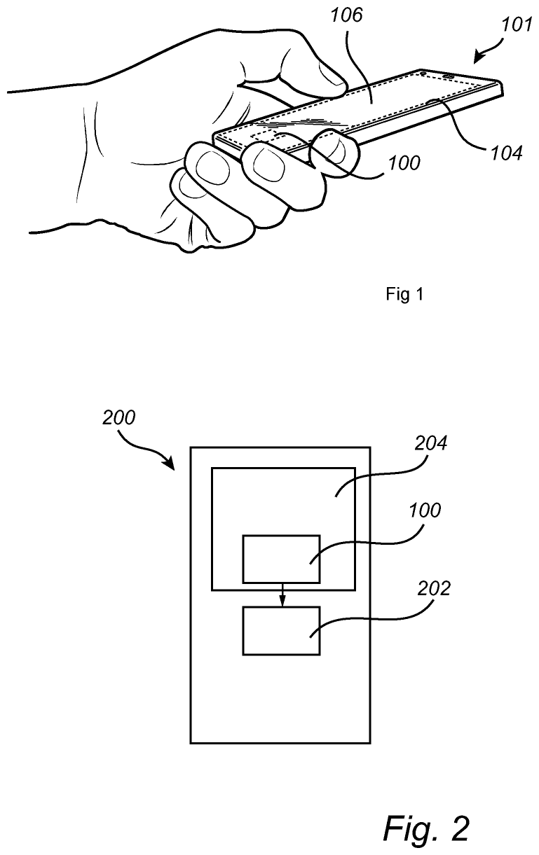

Turning now to the drawings and in particular to FIG. 1, there is schematically illustrated an example of an electronic device configured to apply the concept according to the present disclosure, in the form of a mobile device 101 with an under-display optical fingerprint sensor 100 and a display panel 104 with a touch screen interface 106. The optical fingerprint sensor 100 may, for example, be used for unlocking the mobile device 100 and/or for authorizing transactions carried out using the mobile device 100, etc.

The optical fingerprint sensor 100 is here shown to be smaller than the display panel 104, but still relatively large, e.g., a large area implementation. In another advantageous implementation the optical fingerprint sensor 100 may be the same size as the display panel 104, i.e. a full display solution. Thus, in such case the user may place his/her finger anywhere on the display panel for biometric authentication. The optical fingerprint sensor 100 may in other possible implementations be smaller than the depicted optical fingerprint sensor, such as providing a hot-zone implementation.

Preferably and as is apparent for the skilled person, the mobile device 100 shown in FIG. 1 further comprises a first antenna for WLAN/Wi-Fi communication, a second antenna for telecommunication communication, a microphone, a speaker, and a phone control unit. Further hardware elements are of course possibly comprised with the mobile device.

The embodiments of the present invention especially address fingerprint detection using an optical fingerprint sensor arranged under a display 104 with low, ultra-low or even zero visible light transmittance. The display panel 104 may for example be an AMOLED display with low, or even zero visibility, such as for example a polarizer-less (pol-less) AMOLED display, or an opaque platen with special wavelength transmission, such as infrared light. To solve the ultra-low or zero transmittance, external light sources or modification of the display panel is traditionally required. In other to avoid using lamination and pin-hole solutions that needs display modification and detection layers laminated under the display, the present invention provides a pixel-level collimated emitter with uniform illumination distribution. In case of an ultra-low or even zero visible light transmittance display or cover, the light emitters are preferably configured to emit infrared light, i.e., light in the infrared wavelength range that can be transmitted through the ultra-low or even zero visible light transmittance display or cover. A herein described interleaved array of emitters and photodetectors provide for uniform illumination with a predetermined field of illumination via a collimator structure and detection of reflected light using the photodetectors.

It should furthermore be noted that the invention may be applicable in relation to any other type of electronic devices comprising display panels, such as a laptop, a tablet computer, etc.

FIG. 2 is a schematic box diagram of an electronic device according to embodiments of the invention. The electronic device 200 comprises a display panel 204 with low or zero visible light transmittance and an optical fingerprint sensor 100 conceptually illustrated to be arranged under the display panel 204 according to embodiments of the invention. Furthermore, the electronic device 200 comprises processing circuitry such as control unit 202. The control unit 202 may be stand-alone control unit of the electronic device 202, e.g., a device controller. Alternatively, the control unit 202 may be comprised in the optical fingerprint sensor 100.

The control unit 202 is configured to receive a signal indicative of a detected object from the optical fingerprint sensor 100. The received signal may comprise image data.

Based on the received signal the control unit 202 is configured to detect a fingerprint and based on the detected fingerprint the control unit 202 is configured to perform a fingerprint authentication procedure. Such fingerprint authentication procedures are considered per se known to the skilled person and will not be described further herein.

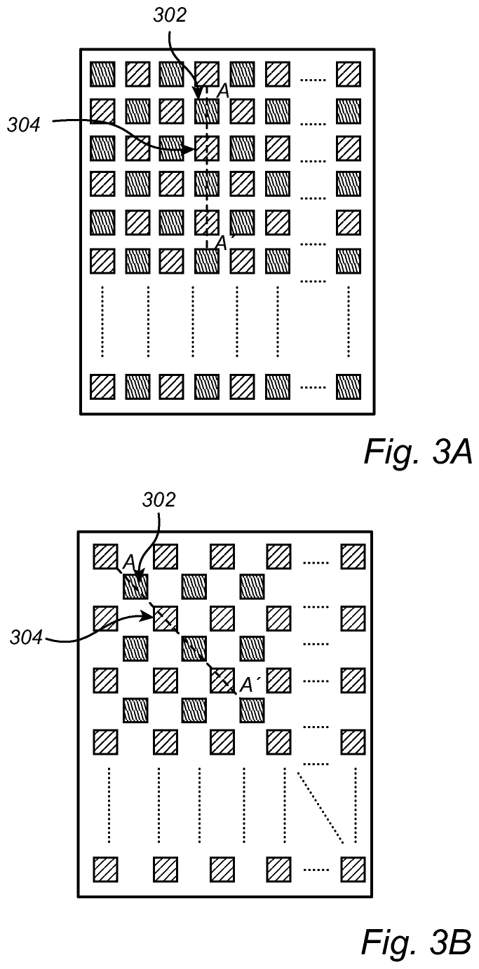

FIGS. 3A-B are conceptual top views of interleaved arrays of light emitters 302 and photodetectors 304. In FIG. 3A the array of light emitters 302 is interleaved with the array of photodetectors 304 in a square crossed arrangement. In FIG. 3B, the array of light emitters 302 is interleaved with the array of photodetectors 304 in an oblique crossed arrangement, here exemplified as a 45-degree oblique arrangement. Each photodetector 304 is surrounded by four equally contributing light emitters 302, except at the edge row and column of the interleaved arrays.

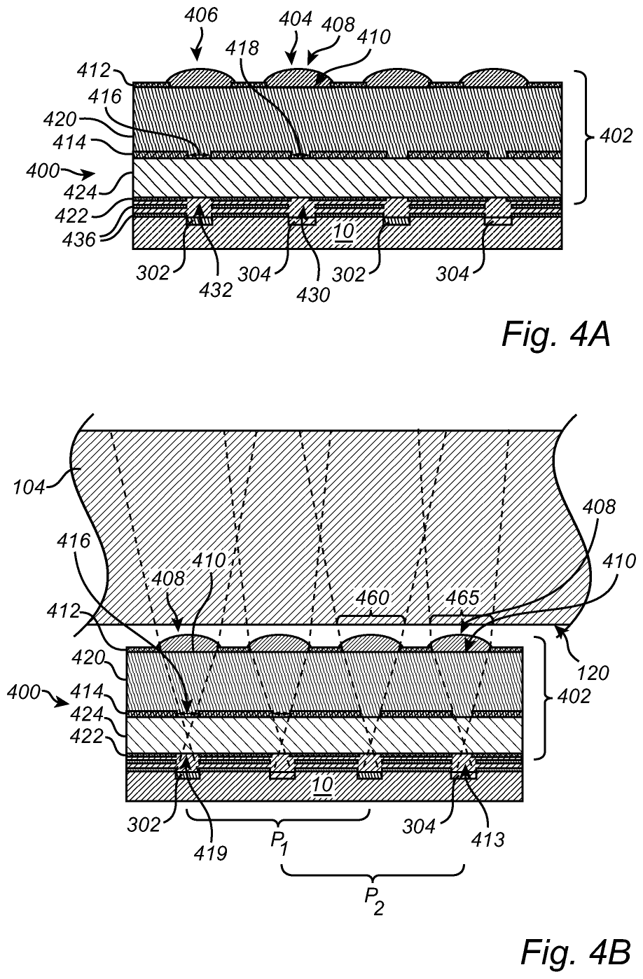

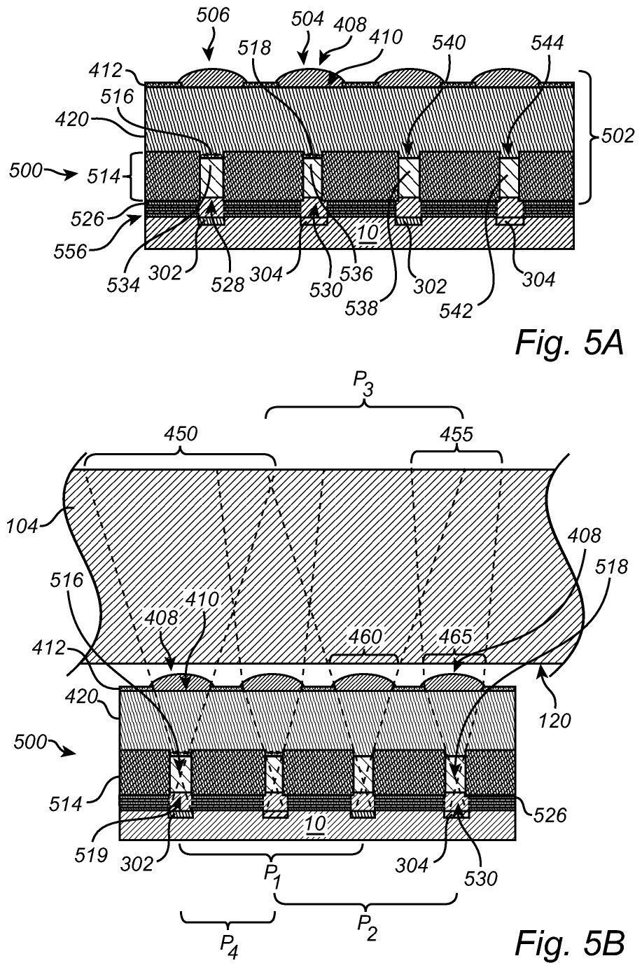

FIG. 4A and FIG. 5A are conceptual cross-sections along A-A′ of two different embodiments of the present invention.

An optical fingerprint sensor 400, 500 is configured to be arranged under a cover structure 104 comprising a display.

The optical fingerprint sensor 400, 500 comprises an array of photodetectors 304 for detecting light transmitted from an object located on an opposite side of the cover structure 104. Further, the optical fingerprint sensor 400, 500 comprises an array of light emitters 302 for illuminating the object. The array of light emitters 302 is interleaved with the array of photodetectors 304-Thus, as shown in FIGS. 3A-B, the array of light emitters 302 and the array of photodetectors 304 are mixed to form a single intermixed array.

A collimator structure 402, 502 is arranged to cover the array of light emitters 302 and the array of photodetectors 304. The collimator structure comprising a first set of collimators 404, 504 aligned with the photodetectors 304 and each being configured to provide a predetermined field of view, and a second set of collimators 406, 506 aligned with the light emitters 302 and each being configured to provide a predetermined field of illumination.

The collimator structure 402, 502 further comprising an array of microlenses 408, wherein each collimator of the first set and the second set comprises an aperture covered with a respective microlens 408. The aperture is provided as an opening 410 of a first opaque layer 412 comprised in the collimator structure 402, 502.

The first opaque layer 412 may be a so-called black matrix or black layer configured to prevent leakage light from slipping to the photodetectors 304 without having passed through a microlens 408. A black layer has transmittance less than 1% for light in the wavelength range of 400 nm to 1100 nm.

The collimator structure 402 and 502 further comprises a second opaque layer 414, 514 having through-holes 416, 418, and 516, 518 aligned with respective light emitters 302 and photodetectors 304. In FIGS. 4A and 5A, the through-holes 416, 418, and 516, 518 are centered with the light emitters 302 and photodetectors 304 along common center axes. However, the through-holes 416, 418, and 516, 518 may be aligned off-centered with the light emitters 302 and photodetectors 304. This provides for emitting or receiving light at an oblique angle instead of at a right angle. The centers of the microlens opening 410, the through-holes 416, 516, and 418, 518, the openings 432 for each light emitter 302 or the openings for each photodetector 430, and the emitter pixel 302 or the photodetector 304 should still be aligned on a straight line, although the straight line passing through the centers may be inclined.

The optical fingerprint sensor further comprises an optically transparent substrate 420 arranged stacked between the array of microlenses 408 and the second opaque layer 414, 514 to cover the second opaque layer. The microlenses 408 and the optically transparent substrate 420 have a transmittance larger than 95% in the wavelength range from 400 nm to 1100 nm.

In one preferred embodiment, the array of light emitters 302 and the array of photodetectors 304 are distributed on a single substrate die 10. However, the array of light emitters 302 and the array of photodetectors 304 may be split on different support structures or dies in a system in package arrangement.

Turning now specifically to the embodiment shown in FIG. 4A. In this embodiment, the collimator structure 402 comprises a third opaque layer 422 and an optical filter layer 424 interleaved between the second opaque layer 414 and the third opaque layer 422. The third opaque layer 422 is arranged closer to the array of photodetectors 304 and the array of light emitters 302 than the second opaque layer 414.

The collimator structure 402 thus comprises a stack of components where the third opaque layer 422, or black layer, is the bottommost layer arranged on the substrate 10 closest to the array of light emitters 302 and photodetectors 304. The optical filter layer 424 is stacked on the third opaque layer 422. The optical filter layer 424 is interleaved or sandwiched between the second opaque layer 414 and the third opaque layer 422. The optical filter layer 424 preferably covers the entire array of light emitters 302 and photodetectors 304. The second opaque layer 414 is stacked on the optical filter layer 424.

The optical filter layer 424 may be configured allow transmission of light in the visible range of light. For example, the spectral transmission band may belong to red light, or green light, blue light, or combinations thereof. Red light may be considered wavelengths in the range of about 600-800 nm. Blue light may be considered wavelengths in the range of about 450-500 nm. Green light may be considered wavelengths in the range of about 500-570 nm.

The optical filter layer 424 may further, or alternatively include an infrared light cut filter to reject transmission of infrared light.

The optical filter layer 424 may further, or alternatively include a bandpass filter centered at about 810 nm, 850 nm or 940 nm.

For example, in applications with ultra-low or zero visible light transmittance of the cover structure, such as for example an opaque cover glass of a liquid crystal display, or a polarizer-less AMOLED, it is advantageous to configure the optical filter layer 424 to allow transmission of infrared wavelength light such as at 850 nm or 940 nm from the light emitters 302 to pass through the cover structure, and to allow the reflected light from object on top of the cover structure that pass through the cover structure to reach and be captured by the photodetectors 304.

The optically transparent substrate 420 is arranged or stacked on the second opaque layer and may for example be a glass or polymer substrate that the optically transparent to allow light to be transmitted into the optically transparent substrate 420 from one side, through the material of the optically transparent substrate 420, and exit at the opposite side of the optically transparent substrate 420.

The first opaque layer 412 is arranged or stacked on the optically transparent substrate 420 with the microlenses in the openings 410. A diameter of the openings 410 substantially match the diameter of the respective microlens 408. However, the diameter of the openings 410 is larger than the diameter or width of the through-holes 416, 418 in the second opaque layer 414. The diameter or width of the through-holes 416 associated with the light emitters 302 is larger than the diameter or width of the through-holes 418 associated with the photodetectors 304.

Furthermore, the third opaque layer 422 includes separate openings 430, 432 for each light emitter 302 and photodetector 304. The diameter or width of the openings 430 for the photodetectors 304 are smaller than a diameter or width of the respective aligned through-holes 418 in the second opaque layer 414. In addition, in this example embodiment, the diameter or width of the openings 430 in the third opaque layer 422 for the photodetectors 304 are smaller than a diameter or width of the through-holes 432 for the light emitters 302.

Turning now specifically to the embodiment shown in FIG. 5A.

The collimator structure here includes through-holes 516 and 518 in the second opaque layer 514 with a different aspect ratio compared to the embodiment in FIG. 4A. The thickness of the second opaque layer 514 is sufficient to accommodate the thickness of the optical filter elements 534, 536 arranged in the through-holes 516, 518 in the second opaque layer 514. The thickness of the second opaque layer 514 is such that the height of the through-holes 516, 518 in the stacking direction of the collimator structure 502 is larger than the width or diameter of the through-holes 516, 518. The thickness of the second opaque layer 514 can be approximately the same as the total thickness of the second opaque layer 414, the optical filter layer 424, and the third opaque layer 422 discussed in relation to in FIG. 4A.

In this embodiment, the second opaque layer 514 is stacked with or arranged on the substrate 10 of the light emitters 302 and photodetectors 304. In embodiment, the second opaque layer 514 is stacked with or arranged on a third opaque layer 526 provided in the form of a metal layer in or on the substrate 10. This metal layer may be part of a frontside illumination pixel structure which often includes more than one metal layer 556.

The metal layer 526 is located between the second opaque layer 514 and the array of photodetectors 304 and light emitters 302. The metal layer 526 having separate openings 528, 530 for each light emitter 302 and photodetector 304. The openings 530 for the photodetectors 304 are smaller than a diameter or width of the respective aligned through-holes 518 of the second opaque layer 514. Further, the diameter or width of the openings 530 for the photodetectors 304 is smaller than a diameter or width of the openings 528 in the metal layer aligned with the light emitters.

In this embodiment, the optically transmissive substrate 420 is stacked with and arranged on the second opaque layer 514.

The collimator structure 502 comprises individual optical filter elements 534, 536 arranged in each of the through-holes 516, 518. The second opaque layer 514 separates the optical filter elements 534, 536 in the plane of the second opaque layer 514. In this way, the optical filter elements 534, 536 form separate filter islands in the second opaque layer 514 where filtered light may pass to/from the photodetectors 304 and light emitters 302. The optical filter elements 534 and 536 may substantially fill the respective through-holes 516 and 518 in the second opaque layer 514.

The optical filter elements 534, 536 may be configured allow transmission of light in the visible range of light. For example, the spectral transmission band may belong to red light, or green light, blue light, or combinations thereof as discussed in relation to FIG. 4A.

The optical filter elements 534, 536 may further, or alternatively include an infrared light cut filter to reject transmission of infrared light.

The optical filter elements 534, 536 may further, or alternatively include a bandpass filter centered at about 810 nm, 850 nm or 940 nm.

For example, in applications with ultra-low or zero visible light transmittance of the cover structure, such as for example an opaque cover glass of a liquid crystal display, or a polarizer-less AMOLED, it is advantageous to configure the optical filter elements 534, 536 to allow transmission of infrared wavelength light such as at 850 nm or 940 nm from the light emitters 302 to pass through the cover structure, and to allow the reflected light from object on top of the cover structure that pass through the cover structure to reach and be captured by the photodetectors 304.

Further, the individual optical filter elements 534, 536 may be of different types having different spectral transmission bands. For example, optical filter elements for the light emitters 302 may comprise at least two different filter element types 534 and 538 arranged in different through-holes 516 and 540 and having different wavelength transmission bands and/or polarization. Similarly, the optical filter elements 536 and 542 for the photodetectors 304 may comprise at least two different filter element types 536 and 542 arranged in different through-holes 518 and 544 and having different wavelength transmission bands and/or polarization. This allows for enabling different light emitter channels and photodetectors channels.

Furthermore, the optical filter elements 534, 538 arranged in the through-holes 516, 540 aligned with the light emitters 302 are different from the optical filter elements 536, 542 arranged in each of the through-holes aligned with the photodetectors.

That optical filter elements are different means that their optical properties are different, for example, that their spectral transmission bands or polarization are different. As a more specific example, the spectral transmission band or polarization of the optical filter elements 534, 538 is different from the spectral transmission band or polarization of the optical filter elements 536, 542.

FIG. 4B conceptually illustrates an optical fingerprint sensor 400 arranged under a cover structure 104 and further showing the illuminated area 450 of a light emitter 302 and the sampling area 455 of a photodetector 304 in the object plane.

Analogously, FIG. 5B conceptually illustrates an optical fingerprint sensor 500 arranged under a cover structure 104 and further showing the illuminated area 450 of a light emitter 302 and the sampling area 455 of a photodetector 304.

A radius of the predetermined field of illumination 450 at an object plane is larger than a half pitch, p₁/2 of the light emitters 302.

Further, a radius of the predetermined field of view 455 in the object plane is here shown to be less than a half pitch, p₂/2, of the photodetectors 304. However, this is not required. Generally, the radius of the predetermined field of view is optimized depending on the radius of the field of illumination.

With further reference to FIG. 4B and FIG. 5B. The field of illumination of the light emitters 302 is determined by the diameter of the opening 410 in the first or top opaque layer 412, the diameter of the opening 416, 516 in the second, or middle, opaque layer 414, 514, the radius of curvature and height of microlens 408, and thickness of transparent substrate 420 and the thickness of the second, or middle, opaque layer 414, 514, the first or top opaque layer 412, the diameter of the through-hole 432 in the third opaque layer 422, and the size of the emitter 302.

The field of view of a photodetector 304 is determined by the diameter of the through-hole 518 in in the second, or middle, opaque layer 414, 514, the diameter of the opening 430 in the bottom third opaque layer or the opening 530 in metal layer 526, a radius of curvature and height of microlenses 408, the thickness of whole collimator structure from the photodetector 304 to the microlens 408, the diameter of the through-hole 430 in the third opaque layer 422, and the size of the photodetector 304.

The diameter of opening 410 aligned with a light emitter 302 is larger than the diameter of the corresponding opening 416, 516 in the second opaque layer. The diameter of the opening 419, 519 in the bottom third opaque layer 422 or metal layer 526 are large enough to not impact the field of illumination.

Also, the diameter of the opening 430 in the bottom third opaque layer or the opening 530 in metal layer 526 aligned with photodetectors 304 is less than the diameter of the opening 418, 518 in the second opaque layer. The diameter of the opening 410 in the first opaque layer, i.e., the top black layer 412 should not impact the field of view significantly.

Further, the area 450 of field of illumination and the area 455 of the field of view at the object plane also depends on parameters such as airgaps between cover structure 104 and the and optical stack 400, 500, and cover structure 104 thickness.

The illuminated area 450 should cover the sampling area 455, so the illuminated radius should be equal or larger than the half pitch p₁/2. The sampling area 455 pitch, p₃ depends on the requirement of image density, dot per inch, DPI, and the sampling radius should be equal or less than the half pitch p₂/2.

For example, if the fingerprint image is required to have DPI larger than 508, the sampling pitch should be less than 50 micrometer.

The pitch p₄ between neighboring light emitters 302 and photodetectors 304, is adapted so that the illuminated area 460 and the sampling area 465 on the cover structure bottom surface 120 do not overlap to avoid that the reflected light from the bottom surface 120 will be captured by the photodetectors, leading to reduced image contrast.

The bottom surface is opposite the top surface 122 touched by an object for fingerprint imaging. The bottom surface 120 is facing towards the optical fingerprint sensor 400, 500.

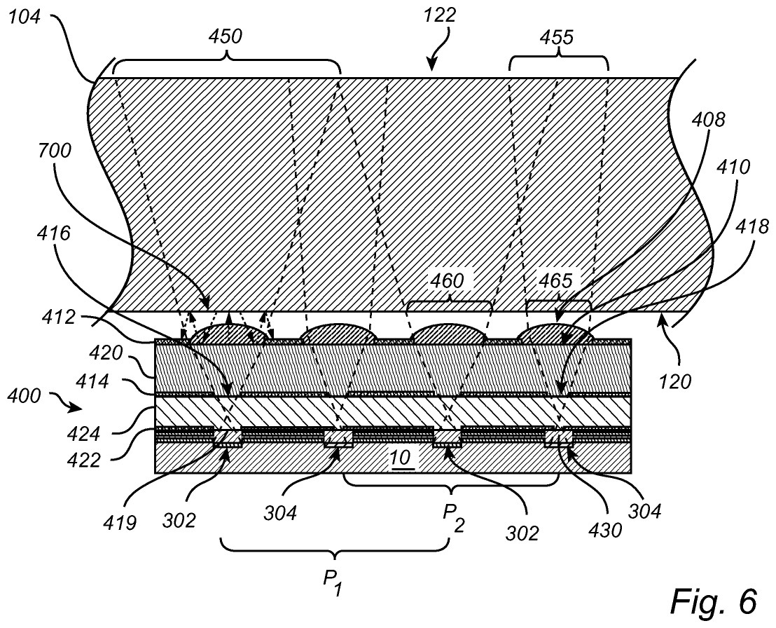

A further advantage of the present invention is now presented. In many presently known arrangements with under display illumination in combination with a camera-based fingerprint sensor is one or more discrete LEDs mounted at an angle to illuminate the fingerprint area. A drawback of this is that only a small fraction, such as 1-10% of the emitted light is transmitted through the display, and a large portion the is instead reflected towards the sensor pixels. Thus, emitted light reflected at the finger and that finally reaches the sensor may be as little as 10⁻⁴ to 10⁻² of the light from the light source, while the reflected light is 0.99 to 0.9 of the light from the light source. Since such traditional sensors has a very large field of view, e.g., 100-130 degrees, it's difficult to avoid straylight from reaching the sensor and drowning the fingerprint signal. With embodiments of the present invention the amount of straylight collected by the photodetectors 304 can be highly suppressed as is conceptually illustrated in FIG. 6. In FIG. 6, conceptual light beams 700 are shown that are reflected off the bottom surface 120 of the cover structure 104. The reflected light is blocked by the top opaque layer 412 to reach back towards the photodetector 304. Further, this top opaque layer 412, e.g., the black matrix layer has low reflectance which suppresses the risk of multiple reflections between the bottom surface 120 of the cover structure 104 and the sensor 400 side. Perhaps even more important, the collimator structures 402, 502 provide for tailoring the angle of the illumination provided by the emitters 302 and the angle of the collected light by the photodetectors 304 as described above with regards to tailoring the field of illumination and the field of view. Further, the microlenses of the emitters may be differently configured compared to the microlenses of the photodetectors to further tailor the angle of the illumination provided by the emitters 302 and the angle of the collected light by the photodetectors 304.

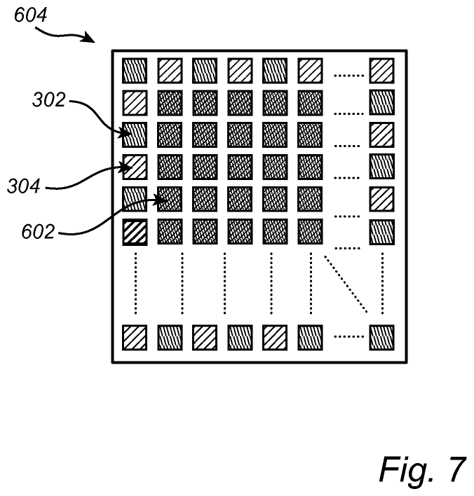

FIGS. 7 is a conceptual top view of interleaved arrays of light emitters 302 and photodetectors 304, and also including capacitive sensing elements 602 interleaved with the array of light emitters 302 and the array of photodetectors 304. In this embodiment, the capacitive sensing elements 602 cover a center portion of the entire combined array 604. The capacitive sensing elements 602 are encircled or encompassed by every second arranged light emitters 302 and photodetectors 304. The capacitive sensing elements 602 are configured to detect a capacitive coupling between an object touching a sensing surface of the optical fingerprint sensor, and provide a sensing signal indicative of the capacitive coupling. This provides for a dual function fingerprint sensor where the capacitive sensor can provide fingerprint authentication functionality and the optical sensor with IR emitters 302 can provide spoof detection.

Preferably, the capacitive sensing elements 602 are arranged on the silicon die 10 as the array of light emitters 302 and the array of photodetectors 304.

The photodetectors 304, or generally pixels of the optical fingerprint sensor 100 are individually controllable photodetectors configured to detect an amount of incoming light and to generate an electric signal indicative of the light received by the detector. The photodetectors 304 be as part of an image sensor such as based on a CMOS, CCD, or thin-film transistor (TFT) technology with associated control circuitry. The operation and control of such photodetectors can be assumed to be known and will not be discussed herein.

The array of light emitters 302 and the array of photodetectors 304 may be arranged in the same plane on the same die.

The microlenses 408 may be arranged or manufactured or the transparent substrate 420. The thickness of the transparent substrate 420 may be in the range of 5 μm to 25 μm.

The light emitters may be for example light-emitting diodes (LEDs), organic light-emitting diodes (OLEDs), or other equally applicable light emitters or light sources. The light emitters are generally controllable to emit light of different color, in different wavelength bands, and with variable intensity. The operation and control of such light emitter can be assumed to be known and will not be discussed herein.

A control unit may include a microprocessor, microcontroller, programmable digital signal processor or another programmable device. The control unit may also, or instead, include an application specific integrated circuit, a programmable gate array or programmable array logic, a programmable logic device, or a digital signal processor. Where the control unit includes a programmable device such as the microprocessor, microcontroller or programmable digital signal processor mentioned above, the processor may further include computer executable code that controls operation of the programmable device. It should be understood that all or some parts of the functionality provided by means of the control unit (or generally discussed as “processing circuitry”) may be at least partly integrated with the optical fingerprint sensor.

Even though the invention has been described with reference to specific exemplifying embodiments thereof, many different alterations, modifications and the like will become apparent for those skilled in the art. Also, it should be noted that parts of the imaging device and method for manufacturing the imaging device may be omitted, interchanged or arranged in various ways, the imaging device yet being able to perform the functionality of the present invention.

Sizes and dimensions of various components and elements shown in the drawings are not necessarily to scale and are generally selected for clarity in the drawings. For example, the thickness of filters, displays, opaque layers, etc., may not correspond to a real implementation.

The microlenses are herein illustrated as plano-convex lenses having the flat surface orientated towards the transparent substrate. It is also possible to use other lens configurations and shapes. A plano-convex lens may for example be arranged with the flat surface towards the display panel, and in one embodiment the lens may be attached to a bottom surface of the display panel even though the imaging performance may be degraded compared to the reverse orientation of the microlens. It is also possible to use other types of lenses such as convex lenses. An advantage of using a plano-convex lens is the ease of manufacturing and assembly provided by a lens having a flat surface.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage.

1. An optical fingerprint sensor configured to be arranged under a cover structure comprising a display, the optical fingerprint sensor comprising:
an array of photodetectors for detecting light transmitted from an object located on an opposite side of the cover structure;
an array of light emitters for illuminating the object, the array of light emitters is interleaved with the array of photodetectors, and
a collimator structure arranged to cover the array of light emitters and the array of photodetectors, the collimator structure comprising a first set of collimators with through-holes aligned with the photodetectors and each being configured to provide a predetermined field of view, and a second set of collimators with through-holes aligned with the light emitters, and each being configured to provide a predetermined field of illumination.

2. The optical fingerprint sensor according to claim 1, wherein a radius of the predetermined field of illumination at an object plane is larger than a half pitch of the light emitters.

3. The optical fingerprint sensor according to claim 1, wherein a radius of the predetermined field of view is less than a half pitch of the photodetectors.

4. The optical fingerprint sensor according to claim 1, wherein the collimator structure further comprises an array of microlenses, wherein each collimator of the first set and the second set comprises an aperture covered with a respective microlens.

5. The optical fingerprint sensor according to claim 4, the collimator structure comprising a first opaque layer, wherein the microlenses are arranged in separate openings of the first opaque layer.

6. The optical fingerprint sensor according to claim 1, the collimator structure comprising:
a second opaque layer having through-holes aligned with respective light emitters and photodetectors.

7. The optical fingerprint sensor according to claim 6, wherein the collimator structure comprises individual optical filter elements arranged in each of the through-holes.

8. The optical fingerprint sensor according to claim 7, wherein the individual optical filter elements comprise at least two different filter element types arranged in different through-holes and having different wavelength transmission bands and/or polarization.

9. The optical fingerprint sensor according to claim 7, therein the optical filter elements arranged in each of the through-holes aligned with the light emitters are different types from the optical filter elements arranged in each of the through-holes aligned with the photodetectors.

10. The optical fingerprint sensor according to claim 6, the optical fingerprint sensor comprising a third opaque layer between the second opaque layer and the array of photodetectors and the array of light emitters, the third opaque layer having separate openings for each light emitter and photodetector, where the openings for the photodetectors are smaller than a diameter of the respective aligned through-holes of the second opaque layer.

11. The optical fingerprint sensor according to claim 6, the collimator structure comprising a third opaque layer and an optical filter layer interleaved between the second opaque layer and the third opaque layer, the third opaque layer being arranged closer to the array of photodetectors and the array of light emitters than the second opaque layer.

12. The optical fingerprint sensor according to claim 11, the third opaque layer having separate openings for each light emitter and photodetector, where the openings for the photodetectors are smaller than a diameter of the respective aligned through-holes in the second opaque layer.

13. The optical fingerprint sensor according to claim 11, the filter layer being arranged to cover the array of photodetectors and the array of light emitters.

14. The optical fingerprint sensor according to claim 4, comprising an optically transparent substrate arranged stacked between the array of microlenses and the second opaque layer to cover the second opaque layer.

15. The optical fingerprint sensor according to claim 1, wherein the array of light emitters is interleaved with the array of photodetectors in a square crossed arrangement.

16. The optical fingerprint sensor according to claim 1, wherein the array of light emitters is interleaved with the array of photodetectors in an oblique crossed arrangement.

17. The optical fingerprint sensor according to claim 1, wherein the array of light emitters and the array of photodetectors are distributed on a single substrate die.

18. The optical fingerprint sensor according to claim 1, further comprising a set of capacitive sensing elements interleaved with the array of light emitters and the array of photodetectors, the capacitive sensing elements are configured to detect a capacitive coupling between an object touching a sensing surface of the optical fingerprint sensor, and to provide a sensing signal indicative of the capacitive coupling.

19. The optical fingerprint sensor according to claims 17, the capacitive sensing elements being arranged on the same silicon die as the array of light emitters and the array of photodetectors.

20. An electronic device comprising:
a cover structure comprising a display;
the optical fingerprint sensor according to claim 1, and
processing circuitry configured to:
receive a signal from the optical fingerprint sensor indicative of a fingerprint of a finger touching the at least partly transparent display panel,
perform a fingerprint authentication procedure based on information comprised in the signal.

21. (canceled)
